(19) United States
(12) Patent Application Publication
(10) Pub. No.: US 2012/0300426 A1
(43) Pub. Date: Nov. 29, 2012

(54) CONNECTION STRUCTURE OF PRINTED CIRCUIT BOARD, METHOD FOR PRODUCING SAME, AND ANISOTROPIC CONDUCTIVE ADHESIVE

(76) Inventors: Masamichi Yamamoto, Osaka-shi (JP); Kyouichirou Nakatsugi, Osaka-shi (JP); Kou Noguchi, Koka-shi (JP); Tetsuga Shimomura, Koka-shi (JP)

(21) Appl. No.: 13/513,434

(22) PCT Filed: Sep. 2, 2010
(86) PCT No.: PCT/JP2010/064990

§ 371 Date: Aug. 7, 2012

(30) Foreign Application Priority Data
Dec. 2, 2009 (JP) 2009-274868

(51) Int. Cl. H05K 1/14; H05K 3/36

(52) U.S. Cl. 361/803; 156/306.6

(57) ABSTRACT

There are provided a connection structure of printed circuit boards, and so forth, the connection structure including a first printed circuit board, a second printed circuit board located above the first printed circuit board, and an anisotropic conductive adhesive configured to establish a conductive connection between a conductor of the first printed circuit board and a conductor of the second printed circuit board, in which the anisotropic conductive adhesive contains a conductive filler, and in which the conductive filler is formed of crystallized metal-particle wires produced by allowing metal particles to crystallize and grow linearly. It is thus possible to easily achieve sufficiently high connection strength while a flying lead of one printed circuit board is electrically connected to a conductive lead (substrate pad) of the other printed circuit board.

### TECHNICAL FIELD

The present invention relates to a connection structure of printed circuit boards, a method for producing the connection structure, and an anisotropic conductive adhesive. More specifically, the present invention relates to a connection structure of printed circuit boards, the connection structure enabling us to establish a connection at a low pressure between high-density circuit boards in electronic devices and so forth, a method for producing the connection structure, and an anisotropic conductive adhesive.

### BACKGROUND ART

Electronic devices often have a structure in which conductive leads on two printed circuit boards are electrically connected to each other. In certain types of electronic devices, a flexible printed circuit board can be arranged along a surface, a side face, and a back face of a mechanical part of an electronic device. In this case, the flexible printed circuit board is bent in the course of the way. Thus, the front and back surfaces are often reversed at its ends. For this reason, in order to improve the flexibility of the components in manufacture, in the application field in which a flexible printed circuit board is used in such a manner that the front and back faces are often reversed at its ends as described above, bare conductive leads, referred to as “flying leads”, which are not provided with an insulating base material and which are capable of establishing an electrical connection at the back face are used as conductive leads of a connection part of the flexible printed circuit board. The flying leads face conductive leads of another component and are connected thereto on the front face side or the back face side. This eliminates the need to prepare a double-sided flexible printed circuit board including conductive leads on the front and back faces of an insulating base material. The flying leads are connected to the conductors of another printed circuit board by, in particular, ultrasonic bonding (see Patent Literature 1). Thereby, a connection structure having high connection strength can be easily produced.

Also in the case of usage different from that of the foregoing printed circuit board, a conductive connection is often established between flying leads of one printed circuit board and conductors of another printed circuit board.

### SUMMARY OF INVENTION

### Technical Problem

However, with a rapid increase in the amount of information treated in electronic devices, trends toward finer pitches of conductors of printed circuit boards have required the development of a connection method corresponding to the finer pitches because ultrasonic bonding can cause a short circuit. Thus, a method has been studied which includes connecting the flying leads to substrate pads of a printed circuit board using an anisotropic conductive adhesive to easily establish an electrical connection. The method for establishing the electrical connection of the flying leads using the anisotropic conductive adhesive can easily correspond to finer pitches of conductors. Unfortunately, the resulting connection is unstable, and the connection strength is not sufficiently high. As specific degradation phenomena, two phenomena are exemplified as main direct phenomena: (D1) The flying leads are deformed and broken by pressure to cause the electrical connection to be unstable, and (D2) the release film is deformed by pressure to cause the ACF between the flying leads to flow out, thereby reducing the connection strength. The phenomena (D1) and (D2) are referred to as degradation phenomena. The common factor among the two degradation phenomena is a high pressure during thermocompression bonding. Thus, if a conductive connection is established at a low pressure such that the deformation of the flying leads and the deformation of the release film are both inhibited, the foregoing problems can be solved.

If a method for establishing a conductive connection by thermocompression bonding at a low pressure such that the flying leads are not deformed is developed, the method for establishing a conductive connection at a low pressure is effective in establishing a connection between conductive leads of two printed circuit boards that do not include a flying lead.

The present invention aims to provide a connection structure of printed circuit boards, a method for producing the connection structure, and an anisotropic conductive adhesive used therefor, whereby conductive leads of two printed circuit boards are subjected to thermocompression bonding at a low pressure such that the conductive leads and a release film are not deformed, so that it is possible to easily establish a stable conductive connection while preventing a reduction in connection strength.

### Solution to Problem

A connection structure of printed circuit boards according to the present invention includes a first printed circuit board, a second printed circuit board located above the first printed circuit board, and an anisotropic conductive adhesive configured to establish a conductive connection between a conductor of the first printed circuit board and a conductor of the second printed circuit board, in which the anisotropic conductive adhesive contains a conductive filler, and in which the conductive filler is formed of crystallized metal-particle wires produced by allowing metal particles to crystallize and grow linearly.

(N1) The anisotropic conductive adhesive is arranged between conductors in the form of a thin film to establish a conductive connection between the conductors, and thus is often referred to as an “anisotropic conductive film”. Furthermore, (N2) a product of the anisotropic conductive adhesive is in the form of a film before use and thus is also referred to as an “anisotropic conductive film”. In this description, the anisotropic conductive film (ACF) includes both (N1) and (N2). That is, the anisotropic conductive adhesive is expressed as the anisotropic conductive film (ACF). In the case where, in particular, (N2) before use is distinguishably expressed, it is described as such. Alternatively, a distinguishable name, such as an “anisotropic conductive adhesive film”, is used.

Each of the crystallized metal-particle wires, as described above, is an elongated metal-particle composite produced by allowing metal particles to crystallize and grow linearly, the composite having a shape like an elongated wire having a surface to which many metal particles are attached. The conductors of the first printed circuit board and the second printed circuit board are electrically connected to each other through the conductive filler in the ACF. The printed circuit boards are connected and fixed to each other with an adhesive resin in the ACF. When the distance between the conductors of the two printed circuit boards is reduced to a distance comparable to the length of the conductive filler in order to subject the conductors to thermocompression bonding, electrical continuity is established between the conductor of the first printed circuit board and the conductor of the second printed circuit board through the conductive filler. In this case, the crystallized metal-particle wires constituting the conductive filler are elongated and have a predetermined level of elasticity. It is thus possible to surely establish an electrical connection even if thermocompression bonding is performed at a low pressure. The term “low pressure” indicates that the pressure is lower than a pressure when an ACF containing, for example, spherical particles serving as a conductive filler is used. The low-pressure thermocompression bonding makes it possible to surely establish electrical continuity and fill the adhesive into spaces between base materials, between side faces, and so forth of the two printed circuit boards (without flowing out), thereby bonding and fixing both members.

Here, the crystallized metal-particle wires may be produced as follows: in a solution containing ferromagnetic metal ions and reducing ions, the ferromagnetic metal ions are reduced and crystallize out. The metal crystallizes out into fine particles in the early stage of crystallization. In a magnetic field, the fine particles are linearly aggregated, and metal particles are allowed to crystallize and grow into linear or wire-like articles. It is recognized that in each crystallized metal-particle wire, the metal particles coalesce into a unified article. This dovetails with the properties, such as low electrical resistance. After the early stage of crystallization, the ferromagnetic metal ions in the solution lead to the formation of a growing layer on the whole of the metal-particle composite of the linear article. Thus, new metal particles are attached to the surface of the linear article to form a protruding portion, so that the diameter of the linear article is overall increased. The metal-particle wire appears to have a larger diameter and a smoother surface at the later stage of growth. However, the protruding portion on the surface of the linear article is clearly identified by increasing the magnification of a scanning electron microscope. Each of the crystallized metal-particle wires has irregularities on its surface. Each crystallized metal-particle wire may appear macroscopically to have a shape like a nodal structure including nodes located at predetermined intervals, depending on conditions, such as the voltage, current, and ion concentration. For example, the crystallized metal-particle wires are formed by incorporating ferromagnetic metal ions into a reducing solution containing trivalent titanium ions or the like and allowing the metal ions to crystallize out into metal articles.

Thus, the metal used for the crystallized metal-particle wires is, for example, a metal or an alloy that can be a ferromagnetic material.

In the connection structure of printed circuit boards according to the present invention, a gap defined as a distance between the conductor of the first printed circuit board and the conductor of the second printed circuit board may be in the range of 0.1 μm to 3.0 μm. The crystallized metal-particle wires have low elasticity and thus make it possible to set the gap between the conductors to 0.1 μm to 3.0 μm even if thermocompression bonding is performed at a low pressure. This eliminates degradation phenomena (D1) and (D2) described above. The foregoing configuration provides the following effects (E1) and (E2): (E1) The deformation and break of flying leads are prevented to stabilize an electrical connection, and (E2) the deformation of a release film is prevented, thus not resulting in the flow out of the ACF between the flying leads.

In contrast, in the case where nickel particles, resin balls plated with gold, or the like are used as the conductive filler, when thermocompression bonding is performed at a low pressure, the gap between the conductors cannot be reduced because of their high elasticity.

In the connection structure of printed circuit boards according to the present invention, the second printed circuit board may include a flying lead serving as the conductor, and the ACF may establish a conductive connection between the conductor of the first printed circuit board and the flying lead of the second printed circuit board. In this case, it is possible to establish a conductive connection between electrodes by thermocompression bonding at a low pressure without causing a short circuit, corresponding to finer pitches of conductors and flying leads with increasing amount of information. Furthermore, it is possible to increase the connection strength between the first printed circuit board and the second printed circuit board.

The reason the connection strength is increased is as follow.

In the conductive connection between the conductor and the flying lead, the ACF is usually allowed to intervene between the first printed circuit board and the second printed circuit board, and thermocompression bonding is performed with a thermocompression bonding tool from the release film. As the release film, a sheet of polytetrafluoroethylene (PTFE) or silicone rubber is used. The purpose of the use of the sheet of PTFE or silicone rubber as the release film is (1) to prevent adhesion of the ACF to the thermocompression bonding tool, and is (2) to absorb variations in the thickness of a compressed component (conductor/ACF/flying lead), the deviation of the setting of the device, and so forth and to appropriately apply a pressure so as not to increase the deviation and so forth during the thermocompression bonding. However, the application of a pressure used in the related art during the thermocompression bonding leads to a high degree of softening due to an increase in temperature. Thus, PTFE or the like is often forced against the ACF from between the flying leads that are significantly deformed by the pressure of the thermocompression bonding tool to allow the molten or semi-molten ACF to flow from between the conductors of the first printed circuit board to the outside. To increase the connection strength between the conductor and the flying lead, a large amount of the ACF needs to be accumulated in spaces between (conductor/flying lead) pairs without flowing to the outside, and the spaces need to be filled with the ACF up to upper portions of side faces of the (conductor/flying lead) pairs to cover the side faces with thick coverings. That is, in the case where thermocompression bonding is performed at a pressure used in the related art using the release film composed of PTFE or the like, a large amount of the ACF often flows to the outside from between the conductors, thereby failing to stably provide high adhesion strength. Hitherto, for example, spherical or granular metal particles, or resin balls plated with a metal have been used as the conductive filler in the ACF. Thus, a predetermined level of pressure has been needed during thermocompression bonding to establish a conductive connection between the conductor and the flying lead, thereby causing the reduction in adhesion strength.

In the present invention, the crystallized metal-particle wires formed by allowing metal particles to crystallize and grow linearly are used as the conductive filler in the ACF. Each of the crystallized metal-particle wires has a high aspect ratio and an elongated shape. The elongated crystallized metal-particle wires appear to be even very thin needles. Thus, the gap between the conductor of the first printed circuit board and the flying lead of the second printed circuit board can be reduced without applying a high pressure because of the low elasticity of the conductive filler, thereby establishing electrical continuity between the conductor and the flying lead.

Hence, there is no need to apply a pressure used in the related art during thermocompression bonding, so that low-pressure mounting can be performed. The gap between the conductor and the flying lead is preferably in the range of about 0.1 to about 3.0 μm and more preferably 0.3 to 2.0 μm. The low-pressure mounting prevents the fact that the release film is forced between the deformed flying leads to cause the ACF to flow out. As a result, the ACF is held between the conductor of the first printed circuit board and the flying lead of the second printed circuit board during the thermocompression bonding, contributing to improvement in the connection strength.

Each of the crystallized metal-particle wires may have a cross section in which many metal particles coalesce or pack, and the metal particles may form many protruding portions on the surface of each of the crystallized metal-particle wires. The protruding portions on the surface makes it possible to provide satisfactory wettability between the conductive filler and an adhesion resin in the ACF, thereby providing high connection strength as the overall adhesive. This results in an increase in connection strength between the first printed circuit board and the second printed circuit board.

In the connection structure of printed circuit boards according to the present invention, each of the crystallized metal-particle wires may have a diameter of 0.3 μm or less. This results in a reduction in the elasticity of the conductive filler interposed between the conductor of the first printed circuit board and the flying lead of the second printed circuit board, thereby reducing the gap at a low pressure. Furthermore, in the case where longitudinal directions of the crystallized metal-particle wires are aligned with the thickness direction of the ACF, anisotropy is likely to be provided, in other words, conductivity is likely to be provided in the thickness direction of the ACF, and non-conductivity is likely to be provided in the in-plane direction of the ACF film. At a diameter exceeding 0.3 μm, the elasticity of the conductive filler is increased, depending on the volume fraction of the crystallized metal-particle wires. Thus, a high pressure is needed in order to reduce the gap.

The diameter of the crystallized metal-particle wires is defined as the average value of diameters of visually thick portions of the crystallized metal-particle wires measured in a photograph taken with a scanning electron microscope at a magnification of ×30,000. The number of fields of view is set to about three or more. The average value of a total of about 20 crystallized metal-particle wires is used.

In the connection structure of printed circuit boards according to the present invention, the volume fraction of the crystallized metal-particle wires contained in the ACF may be 0.1% by volume or less. This reduces the elasticity of the conductive filler interposed between the conductor of the first printed circuit board and the flying lead of the second printed circuit board and reduces the gap at a low pressure. Furthermore, this makes it easy to impart conductivity to the ACF in the thickness direction and non-conductivity to the ACF in the in-plane direction of the film. A volume fraction of the crystallized metal-particle wires exceeding 0.1% by volume results in high elasticity of the conductive filler, so that a high pressure can be required.

In the connection structure of printed circuit boards according to the present invention, the aspect ratio, i.e., length/diameter, of each of the crystallized metal-particle wires may be 5 or more. This enables us to perform the low-pressure mounting, thereby increasing connection strength between the first printed circuit board and the second printed circuit board.

The length of the crystallized metal-particle wires is defined as the average value of linear distances between first ends and second ends of the crystallized metal-particle wires in an optical micrograph at a magnification of ×1,000. The number of fields of view is set to about 20 or more. The average value of a total of about 100 crystallized metal-particle wires is used.

In the connection structure of printed circuit boards according to the present invention, the crystallized metal-particle wires may be arranged along the direction of connection between the conductor of the first printed circuit board and the conductor the second printed circuit board. That is, the crystallized metal-particle wires are oriented along the thickness direction in the ACF. Thus, electrical continuity between the electrodes is established by low-pressure mounting. The low-pressure mounting increases the connection strength between the first and second printed circuit boards.

An ACF according to the present invention establishes a conductive connection between a conductor of a first printed circuit board and a conductor of a second printed circuit board that is located above the first printed circuit board. The ACF includes a conductive filler, the conductive filler is formed of crystallized metal-particle wires formed by allowing metal particles to crystallize and grow linearly.

According to the foregoing configuration, a conductive connection between the conductors of the two printed circuit boards can be realized by thermocompression bonding at a low pressure. As a result, for example, in the case where one printed circuit board includes flying leads serving as conductors and where a conductive connection between the flying leads and the conductor of the other printed circuit board is established by thermocompression bonding using a release film, the degradation phenomena (D1) and (D2) are inhibited. For example, the use of the crystallized metal-particle wires as a conductive filler results in the following effects (E1) and (E2): (E1) The deformation and break of the flying leads are prevented to stabilize an electrical connection, and (E2) the deformation of the release film is prevented, thus not resulting in the flow out of the ACF between the flying leads. Thus, the two printed circuit boards are connected with high mechanical connection strength.

In the connection structure of printed circuit boards according to the present invention, the ACF may be in the form of a film. This facilitates thermocompression bonding treatment to establish a conductive connection between the conductors of the two printed circuit boards.

In the ACF, the crystallized metal-particle wires may be oriented in the thickness direction of the film. This facilitates low-pressure mounting and facilitates the realization of anisotropic conductivity.

A method for producing a connection structure of printed circuit boards according to the present invention includes the steps of preparing a first printed circuit board, arranging an anisotropic conductive adhesive film on the first printed circuit board, arranging a second printed circuit board on the anisotropic conductive adhesive film so as to correspond to the first printed circuit board, and performing thermocompression bonding by applying a pressure from the second printed circuit board using a thermocompression bonding tool via a release film. In the step of arranging the anisotropic conductive adhesive film, a conductive filler contained in the anisotropic conductive adhesive film is formed of crystallized metal-particle wires formed by allowing metal particles to crystallize and grow linearly.

When the distance between the conductors of the two printed circuit boards is reduced to a distance comparable to the length of the conductive filler in order to subject the conductors to thermocompression bonding, electrical continuity is established between the conductor of the first printed circuit board and the conductor of the second printed circuit board through the conductive filler. In this case, the crystallized metal-particle wires constituting the conductive filler are elongated and have a predetermined level of elasticity. It is thus possible to surely establish an electrical connection even if thermocompression bonding is performed at a low pressure. The low-pressure thermocompression bonding makes it possible to surely establish electrical continuity and hold the adhesive into spaces between base materials, between side faces, and so forth of the two printed circuit boards, thereby bonding and fixing both members.

In the thermocompression bonding step, a gap defined as a distance between the conductor of the first printed circuit board and the conductor of the second printed circuit board may be set in the range of 0.1 μm to 3.0 μm. Furthermore, in the thermocompression bonding step, the pressure may be set to 2 MPa or less. It is thus possible to achieve high connection strength between the first printed circuit board and the second printed circuit board.

### Advantageous Effects of Invention

According to the connection structure of printed circuit boards and so forth of the present invention, the conductive leads of the two printed circuit boards are subjected to thermocompression bonding at a low pressure such that the conductive leads and the release film are not deformed, so that it is possible to easily establish a stable conductive connection while preventing a reduction in connection strength.

### BRIEF DESCRIPTION OF DRAWINGS

FIG. 1A is a plan view illustrating a connection structure of printed circuit boards according to an embodiment of the present invention.

FIG. 1B is a cross-sectional view taken along line IB-IB of FIG. 1A which is a plan view illustrating a connection structure of printed circuit boards according to an embodiment of the present invention.

FIG. 1C is an enlarged view illustrating a gap of the connection structure of the printed circuit boards according to the embodiment of the present invention.

FIG. 2 illustrates a state in which conductors of the printed circuit board illustrated in FIGS. 1A to 1C are connected to flying leads of a second printed circuit board.

FIG. 3 illustrates a thermocompression bonding process.

FIG. 4 illustrates crystallized Ni-particle wires (corresponding to the field of view of an optical microscope).

FIG. 5A is a SEM photograph (×30,000) of a crystallized Ni-particle wire.

FIG. 5B is a schematic diagram of FIG. 5A.

FIG. 6 illustrates flying leads deformed by thermocompression bonding in a connection structure of printed circuit boards of the related art.

FIG. 7 illustrates a state after ACF flows out by thermocompression bonding in a connection structure of printed circuit boards of the related art.

### DESCRIPTION OF EMBODIMENTS

Embodiments of the present invention will be described below with reference to the drawings. In the drawings, the same or equivalent elements are designated using the same reference numerals, and descriptions are not redundantly repeated. The ratios of dimensions in the drawings are not always the same as those of the actual objects described in the respective drawings.

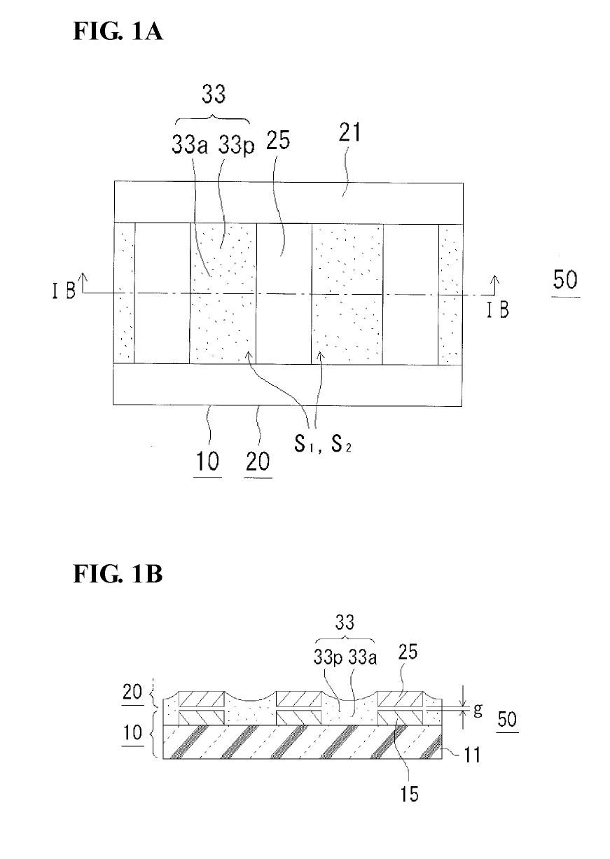

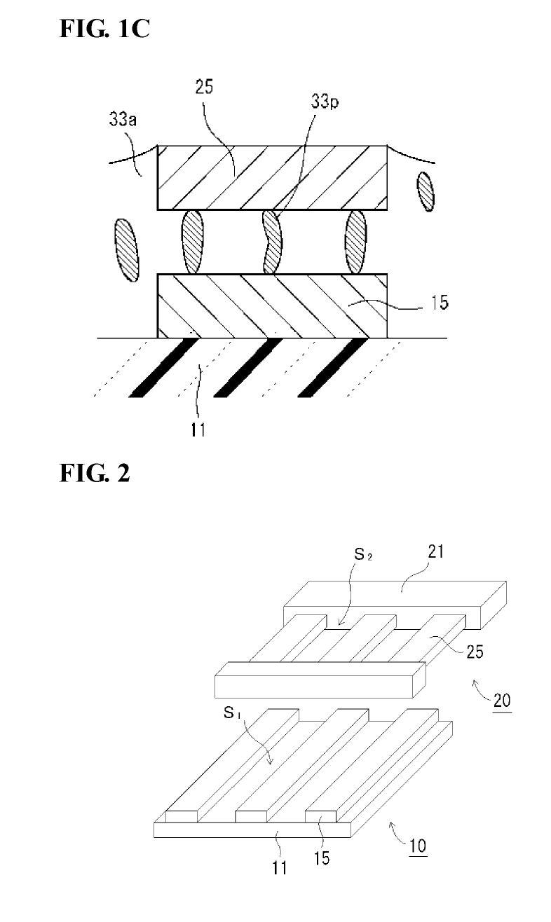

FIG. 1 illustrates a connection structure of printed circuit boards according to an embodiment of the present invention. FIG. 1A is a plan view. FIG. 1B is a cross-sectional view taken along line IB-IB. FIG. 1C illustrates a conductive filler or crystallized metal-particle wires in a gap defined as a distance between a conductor and a flying lead.

A connection structure 50 of the printed circuit boards is a laminate typically including (first printed circuit board 10 having conductive leads 15 on base material 11/anisotropic conductive film (ACF) 33/second printed circuit board 20 having flying leads 25).

In the first printed circuit board 10, the conductive leads (hereinafter, referred to as “conductors”) 15 formed by bonding, for example, copper foil onto the insulating base material 11 and patterning the foil by etching are juxtaposed at regular intervals. In the first printed circuit board 10, the exposed conductors 15 arranged on the insulating base material 11 serve as connection portions and are also referred to as “substrate pads”.

The ACF 33 includes crystallized metal-particle wires (hereinafter, referred to as “CMPWs”) 33p serving as a conductive filler and a thermosetting resin 33a serving as an adhesive. A conductive connection is established between the conductors 15 and the flying leads 25 by the ACF 33. The conductive connection between the conductors 15 and the flying leads 25 is achieved by reducing the distance therebetween to a distance comparable to the length of CMPWs 33p in the thermosetting or thermoplastic adhesive resin. The gap g between the conductors 15 and the flying leads 25 between which the conductive connection is established is, for example, 1 μm and may be in the range of 0.1 μm to 3.0 μm. As illustrated in FIG. 1B, the ACF 33 intervenes between the conductors 15 and the flying leads 25. In particular, the CMPWs 33p serve to establish the conductive connection. The CMPWs 33p are linear or wire-like metal-particle composites formed by allowing metal particles to crystallize and grow linearly, and its production method will be described in detail below.

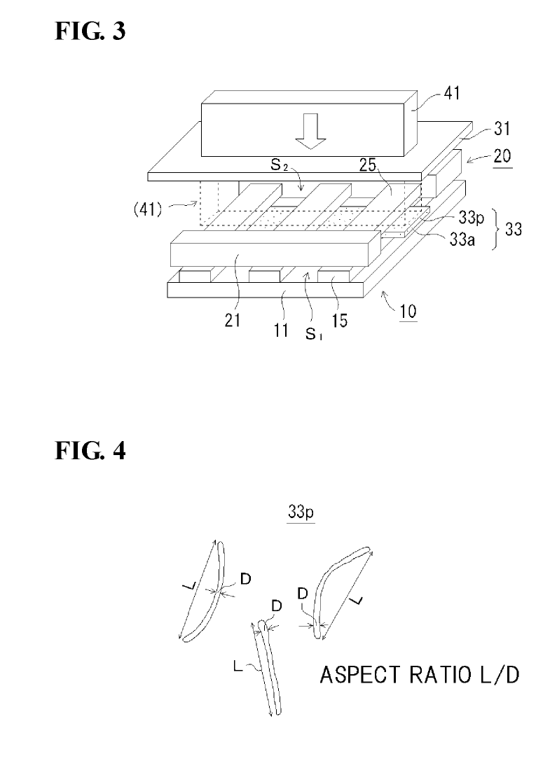

FIGS. 2 and 3 illustrate a method for producing a connection structure configured to connect the conductors 15 on the first printed circuit board 10 and the flying leads 25 of the second printed circuit board 20. As illustrated in FIG. 2, the flying leads 25 are arranged so as to conform to the conductors 15 on the first printed circuit board 10 in plan. The width of each space S₂ between the flying leads 25, i.e., the spacing between the flying leads, is matched to the width of each space S₁ between the conductors 15, i.e., the spacing between the conductors 15. Each of the spaces S₁ between the conductors 15 on the first printed circuit board 10 opens laterally and upward.

In the second printed circuit board 20, one end of each of the flying leads 25, which serve as conductive leads, extends from an insulating base material 21, and the other end thereof reaches the insulating base material 21. Each flying lead is bare between the one end and the other end. In each of the flying leads 25, as illustrated in FIG. 2, both ends may reach the insulating base material 21 to form a lead. Alternatively, the other end may be terminated in a bare state. In the case where a plurality of regions including the flying leads are arranged, the regions may be juxtaposed or arranged in a staggered configuration (for three or more regions).

As illustrated in FIG. 3, the ACF 33 is arranged between the conductors 15 and the flying leads 25 so as to intersect all juxtaposed conductors 15. Thus, the ACF 33 establishes electrical continuity between the flying leads 25 and the conductors 15 to which a pressure is applied. With respect to thermocompression bonding conditions, the thermocompression bonding may be performed at a temperature of 100° C. to 300° C., a holding time of 5 seconds to 45 seconds, and a pressure of 0.2 MPa to 2 MPa. For example, the thermocompression bonding may be performed at a temperature of 200° C., a holding time of 15 seconds, and a pressure of 1 MPa. The pressure is about 3 MPa in the related art. The temperature indicates a temperature of the ACF 33. Thus, a temperature of 200° C. in the foregoing thermocompression bonding conditions indicates that a thermocompression bonding tool 41 containing a heater is set to a higher temperature in such a manner that the temperature of the ACF 33 is 200° C. The holding time is the length of time that pressing is performed with the press tool 41.

A release film 35 used during the thermocompression bonding may be composed of a fluorocarbon-based resin, such as polytetrafluoroethylene (PTFE), which is less likely to adhere to the adhesive resin. To function as a release film, the thickness may be in the range of 10 μm to 300 μm and, for example, 50 μm. In the case where a silicone rubber sheet is used, the thickness may be in the range of 100 μm to 250 μm and desirably, for example, 200 μm.

As described above, the ACF 33 mainly contains a thermosetting resin or a thermoplastic resin. The thermosetting resin experiences a molten or semi-molten state in a transient temperature range lower than a curing temperature. The thermoplastic resin is in a molten or semi-molten state at a high temperature. The application of a pressure to the ACF in the molten or semi-molten state reduces the distance between the conductors 15 and the flying leads 25, so that the CMPWs 33p in the ACF 33 establish electrical continuity between the conductors 15 and the flying leads 25 as illustrated in FIG. 1C. As illustrated in FIG. 1C, each of the CMPWs 33p is elongated and has elasticity, and thus establishes electrical continuity in the gap g between the conductors 15 and the flying leads 25 while undergoing elastic deformation. The CMPWs 33p have low elasticity. This results in a reduction in pressure required to reduce the gap g. It is thus possible to establish a conductive connection at a lower pressure in thermocompression bonding than that in the related art. The low-pressure mounting prevents flow out of the molten or semi-molten resin 33a of the ACF. That is, degradation phenomena (D1) and (D2) are prevented, thus providing the effects (E1) and (E2).

The press tool (thermocompression bonding tool) 41 having a width dimension that falls within the range of the length of the flying leads 25 exposed may be used in the thermocompression bonding. The release film 31 intervenes between the press tool 41 and the flying leads 25. The release film 31 is arranged to prevent adhesion of the ACF 33 to the press tool 41. The release film 31 may be formed of, for example, a PTFE film, or a silicone rubber sheet from the viewpoint of a low-adhesion resin film. During the thermocompression bonding, the press tool 41, illustrated in FIG. 3, of a thermocompression bonding apparatus, the first and second printed circuit boards 10 and 20, and so forth are placed in an ambient atmosphere.

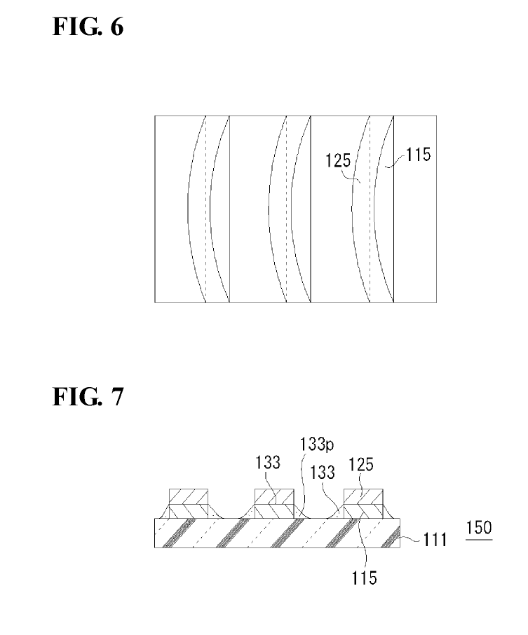

A method for establishing an electrical connection of flying leads using an anisotropic conductive film can be employed for finer-pitch conductors but disadvantageously provides unstable connection and insufficient connection strength. Hitherto, a high pressure of, for example, about 3 MPa, has been used at the time of thermocompression bonding. Such a high pressure causes deformation of flying leads 125 as illustrated in FIG. 6. The application of pressure from a deformed release film, which is not illustrated, causes an ACF 133 containing a granular conductive filler 133p to flow (see FIG. 7). That is, the two foregoing degradation phenomena (D1) and (D2) occur. A connection structure 150 of the related art will be described with reference to the drawings. In FIG. 6, reference numeral 115 denotes lower leads (conductors). In FIG. 7, reference numeral 111 denotes a base material.

In the embodiment of the present invention, the CMPWs 33p are used as a conductive filler in the ACF 33. Thus, the thermocompression bonding tool 41 is pressed against the release film 31 and the flying leads 25 at a low pressure, thereby leading to only a small deformation of the flying leads 25. Furthermore, the low pressure prevents the ACF 33 from flowing out.

As a result, as illustrated in FIG. 1B, the ACF is accumulated in the spaces between (conductor 15/flying lead 25) pairs. The spaces are filled with the ACF up to upper portions of side faces of the (conductor 15/flying lead 25) pairs, thus contributing to improvement in connection strength. The ACF 33 adheres to the side faces of the (conductor 15/flying lead 25) pairs in the molten or semi-molten state. Thus, as illustrated in FIG. 1B, in each of the spaces S between the (conductor 15/flying lead 25) pairs, the ACF does not have a flat surface but has a sagging surface having an intermediate portion with sloping sides, such a surface shape being characteristic of a viscous fluid. A large amount of the ACF 33 accumulated does not result in steeply sloping sides. Steeply sloping sides and a small amount of the ACF result in thin or substantially no coverings on the side faces of the (conductor 15/flying lead 25) pairs as illustrated in FIG. 7, thereby reducing the connection strength.

Both the first and second printed circuit boards 10 and 20 may be flexible printed circuit boards (FPCs) or may be other types of printed circuit boards. In the case of the flexible printed circuit boards, resins, such as polyimide, polyester, and glass epoxy boards, which are generally usable for printed circuit boards, may be used for the insulating base materials 11 and 21. In particular, when it is preferred to have high heat resistance in addition to flexibility, for example, polyamide resins and polyimide resins, such as polyimide and polyamide-imide, are preferably used. The first printed circuit board 10 need not be reinforced. If the first printed circuit board 10 is reinforced, reinforcement may be provided from its back face. When reinforcement is provided from its back face, for example, a glass epoxy board, a polyimide board, a polyethylene terephthalate (PET) board, or a stainless steel board with an appropriate thickness may be bonded.

The conductors 15 or the flying leads 25 may be formed by processing metal foil, such as copper foil, by etching in the usual manner. Alternatively, the conductors 15 may be formed by a semi-additive method using plating. Furthermore, the conductors 15 may be formed by the application of, for example, a Ag paste by printing. Each of the conductors 15 may have a thickness of 10 μm to 40 μm and, for example, 18 μm. Each of the flying leads 25 may have a thickness of 10 μm to 25 μm and, for example, 20 μm.

Next, the CMPWs 33p in the ACF 33 will be described. The CMPWs 33p may be produced by a reduction precipitation method. The reduction precipitation method for the CMPWs 33p is described in detail in Japanese Unexamined Patent Application Publication No. 2004-332047 and so forth. The reduction precipitation method introduced herein is a method using trivalent titanium (Ti) ions serving as a reducing agent. Metal particles (e.g., Ni particles) precipitated contain a trace amount of Ti. Thus, whether metal particles are produced by the reduction precipitation method using trivalent titanium ions or not can be determined by quantitative analysis of the Ti content. Intended metal particles can be produced by changing metal ions present together with trivalent titanium ions. In the case of Ni, Ni ions are allowed to coexist. The addition of a trace amount of Fe ions forms crystallized Ni-particle wires 33p containing a trace amount of Fe.

To form the CMPWs 33p, the metal needs to be a ferromagnetic metal, and the metal particles need to have a predetermined size or more. Both Ni and Fe are ferromagnetic metals. Thus, the crystallized metal-particle wires can be easily formed. The size requirement is needed in a process in which magnetic domains of a ferromagnetic metal are formed and bonded to each other by magnetic force, the metal is precipitated while the bonding state is maintained, and a metal layer grows into a unified metal body. Even after the metal particles having the predetermined size or more are bonded to each other by magnetic force, the metal continues to precipitate. For example, necks of boundaries between the bonded metal particles grow thickly together with other portions of the metal particles. The average diameter D of the CMPWs 33p may be in the range of, for example, 5 nm to 300 nm (0.3 μm) inclusive. The average length L may be in the range of, for example, 0.5 μm to 1000 μm inclusive. The aspect ratio expressed by (length L/diameter D) may be 5 or more. However, dimensions outside these ranges may be acceptable. In this embodiment, the proportion of the CMPWs 33p in the ACF 33 may be in the range of 0.0001% by volume to 0.1% by volume inclusive.

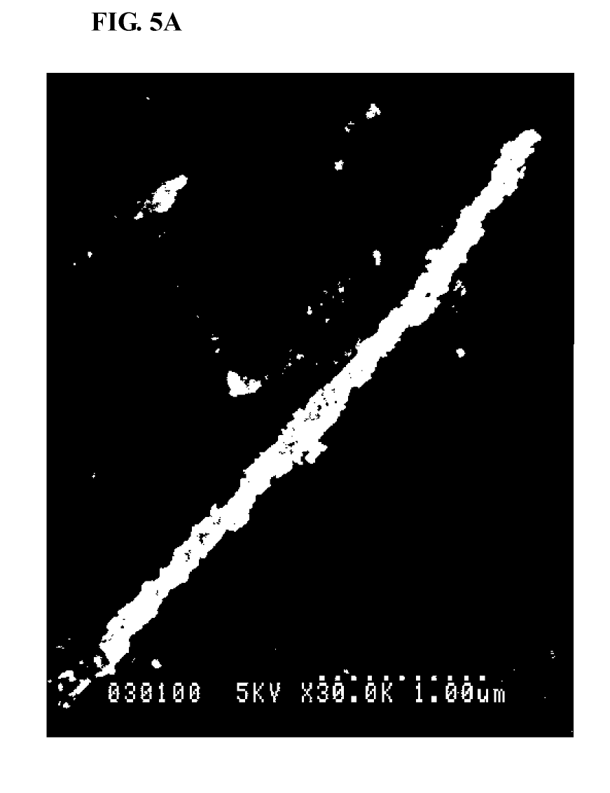

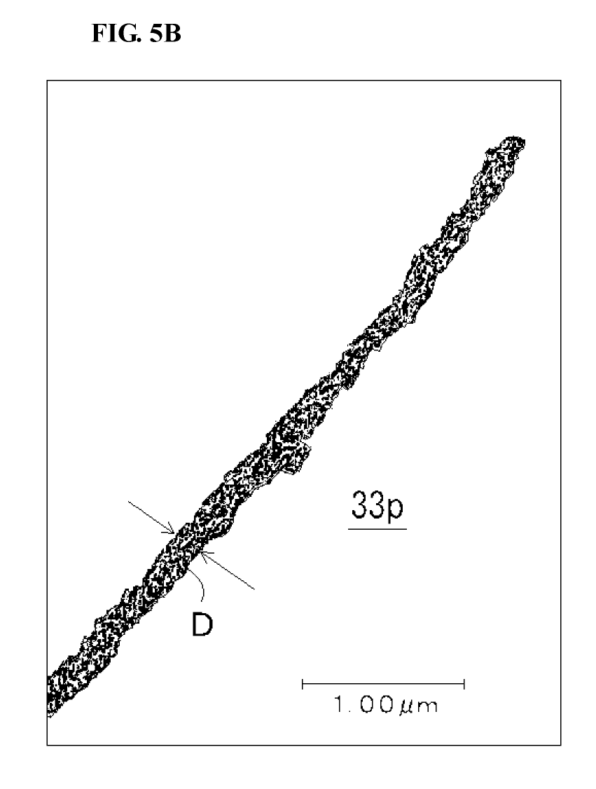

FIG. 4 illustrates the crystallized Ni-particle wires 33p. The crystallized Ni-particle wires 33p are observed with an optical microscope at a magnification of ×100 to ×500. The diameter D is determined by measuring the visually thickest portion. The length L is defined as a linear distance between a first end and a second end. The thickness is not measured with the optical microscope. To explain the aspect ratio, the diameter D is conceptually illustrated in FIG. 4. FIG. 5A is a SEM photograph (×30,000) of the crystallized Ni-particle wires 33p. FIG. 5B is a schematic view thereof. In the case where the diameter D is measured in the SEM photograph, the measurement is performed at the thickest portion excluding a specifically protruding portion.

The diameter D, the length L, and the aspect ratio of the CMPWs 33p are measured as described below. The length of the CMPWs 33p is defined as the average value of linear distances between the first ends and the second ends of the CMPWs 33p in an optical micrograph at a magnification of ×1,000. The number of fields of view is set to about 20 or more. The average value of a total of about 100 CMPWs 33p is used. The diameter D of the CMPWs 33p is defined as the average value of diameters of visually thick portions of the CMPWs 33p measured in a photograph taken with a scanning electron microscope at a magnification of ×30,000. The number of fields of view is set to about three or more. The average value of a total of about 20 CMPWs 33p is used.

In the case where a thermosetting adhesive resin is used as the adhesive resin 33a, the thermosetting adhesive resin essentially contains an epoxy resin, a phenoxy resin, which is a high-molecular-weight epoxy resin, a curing agent, and electrically conductive particles. As the ACF 33, for example, a resin which contains an epoxy resin and a phenoxy resin, which are insulating thermosetting resins and serve as main components, may be used, the CMPWs 33p being dispersed therein. The use of the epoxy resin makes it possible to improve the film-forming performance, heat resistance, and adhesion strength of the ACF 33. If the ACF 33 is in the form of a film, the thickness of the ACF 33 may be in the range of 15 μm to 45 μm and, for example, 35 μm.

Examples of an epoxy resin that may be used as the epoxy resin 33a contained in the ACF 33 include epoxy resins from bisphenol A, F, S, and AD; copolymer-type epoxy resins from bisphenol A and bisphenol F; naphthalene-type epoxy resins; novolac-type epoxy resins; biphenyl-type epoxy resins; and dicyclopentadiene-type epoxy resins. The ACF 33 may contain at least one of these epoxy resins.

The molecular weights of the epoxy resin and the phenoxy resin may be appropriately selected in view of performance required for the ACF 33. For example, the use of a high-molecular-weight epoxy resin results in high film-forming performance and high melt viscosity of the resin at a connection temperature, thereby providing the effect of establishing connection without disturbing the orientation of the electrically conductive particles described below. The use of a low-molecular-weight epoxy resin results in high crosslink density, thereby providing the effect of improving heat resistance. Furthermore, the epoxy resin reacts rapidly with the foregoing curing agent during heating, thereby providing the effect of enhancing adhesion performance. It is thus preferred to use a combination of a high-molecular-weight epoxy resin having a molecular weight of 15,000 or more and a low-molecular-weight epoxy resin having a molecular-weight of 2,000 or less from the viewpoint of achieving well-balanced performance. The blending quantities of the high-molecular-weight epoxy resin and the low-molecular-weight epoxy resin may be appropriately selected. The term “mean molecular weight” used here indicates a weight-average molecular weight in terms of polystyrene determined by gel permeation chromatography (GPC) using a developing solvent consisting of THF.

The ACF 33 contains a latent hardener serving as a curing agent. The incorporation of the curing agent to accelerate the curing of the epoxy resin results in high adhesive strength. Although the latent hardener has excellent storage stability at a low temperature and is much less likely to cause a curing reaction at room temperature, the latent hardener rapidly causes the curing reaction by heat, light, or the like. Examples of the latent hardener include hardeners of imidazole types, hydrazide types, amine types, such as boron trifluoride-amine complexes, amine imides, polyamine types, tertiary amines, and alkyl urea types, dicyandiamide types, acid anhydride types, phenol types, and modified materials thereof. These may be used separately or in combination as a mixture of two or more.

Among these latent hardeners, imidazole-type latent hardeners are preferably used from the viewpoint of excellent storage stability at low temperatures and fast-acting properties. Known imidazole-type latent hardeners may be used as the imidazole-type latent hardeners. More specifically, adducts of imidazole compounds and epoxy resins are exemplified. Examples of imidazole compounds include imidazole, 2-methylimidazole, 2-ethylimidazole, 2-propylimidazole, 2-dodecylimidazole, 2-phinylimidazole, 2-phinyl-4-methylimidazole, and 4-methylimidazole.

In particular, microencapsulated latent hardeners each formed by coating a corresponding one of the foregoing latent hardeners with a high molecular material of, for example, polyurethane type or polyester type, or with a metal thin film composed of nickel or copper and an inorganic substance, such as calcium silicate, are preferred because they are able to successfully strike a balance between long-life nature and fast curing, which are a trade-off relationship. Thus, microencapsulated imidazole-type latent hardeners are particularly preferred.

While the use of the thermosetting adhesive for the ACF 33 has been described in detail, a thermoplastic resin may be used, as described above.

### EXAMPLES

Three specimens of Examples A1 to A3 were produced, the specimens each including the connection structure 50 of printed circuit boards illustrated in FIG. 1. For comparison purposes, connection structures of printed circuit boards were produced, the connection structures containing Ni particles and so forth serving as conductive fillers in ACFs. Table illustrates the production conditions of the specimens. With respect to a test, each of the ACFs 33 was interposed between evaluation board I (corresponding to the first printed circuit board 10 illustrated in FIG. 2) and evaluation board II including flying leads (corresponding to the second printed circuit board 20 illustrated in FIG. 2) and was subjected to thermocompression bonding by the method illustrated in FIG. 3. In each of Examples A1 to A3, each ACF 33 contained CMPWs serving as a conductive filler. In contrast, in each of Comparative Examples B1 and B3, Ni particles were used as a conductive filler in the ACF. In Comparative Examples B2 and B4, gold-plating resin balls were used as a conductive filler.

After the thermocompression bonding, the adhesion strength and a temporal change in electrical resistance in a high-temperature and high-humidity tank were measured. Table illustrates the results. The adhesion strength was indicated by an adhesion-strength ratio when the adhesion strength in Example A1 was defined as 1.

TABLE

| | | | | | | Electrical resistance | | |
|---|---|---|---|---|---|---|---|---|
| | | | | | | (Ω) | | |
| | | | | | | Elapsed time in | | |
| | | Thermocompression | | | | high-temperature and | | |
| | | bonding | | Gap | Adhesion- | high-humidity tank | | |
| | ACF | Pressure | Temperature | g | strength | 0 | 250 | 500 |
| Specimen | Conductive filler | MPa | ° C. | μm | ratio | hours | hours | hours |
| Example | Type: CMPW | 1 | 200 | 0.5 | 1 | 2.5 | 2.6 | 2.6 |
| A1 | Diameter: 0.1 μm | | | | | | | |
| | Length: 3 μm | | | | | | | |
| | Aspect ratio: 30 | | | | | | | |
| Example | Type: CMPW | 1 | 200 | 1.0 | 1 | 2.6 | 2.8 | 2.8 |
| A2 | Diameter: 0.3 μm | | | | | | | |
| | Length: 3 μm | | | | | | | |
| | Aspect ratio: 10 | | | | | | | |
| Example | Type: CMPW | 0.5 | 200 | 0.7 | 1.2 | 2.5 | 2.7 | 2.7 |
| A3 | Diameter: 0.1 μm | | | | | | | |
| | Length: 3 μm | | | | | | | |
| | Aspect ratio: 30 | | | | | | | |
| Comparative | Type: Ni particles | 3 | 200 | 2.5 | 0.2 | 2.5 | 3.2 | 3.8 |
| Example | Diameter: 5 μm | | | | | | | |
| B1 | Aspect ratio: about 1 | | | | | | | |
| Comparative | Type: Gold-plating | 3 | 200 | 2.0 | 0.2 | 2.6 | 3.1 | 3.9 |
| Example | resin balls | | | | | | | |
| B2 | Diameter: 3 μm | | | | | | | |
| | Aspect ratio: about 1 | | | | | | | |
| Comparative | Type: Ni particles | 1 | 200 | 4.8 | 0.9 | 5.8 | 11.5 | Open |
| Example | Diameter: 5 μm | | | | | | | |
| B3 | Aspect ratio: about 1 | | | | | | | |
| Comparative | Type: Gold-plating | 1 | 200 | 3.5 | 0.9 | 8.7 | Open | Open |
| Example | resin balls | | | | | | | |
| B4 | Diameter: 3 μm | | | | | | | |
| | Aspect ratio: about 1 | | | | | | | |

Evaluation board I base material: 25-μm-thick polyimide, leads: 18-μm-thick Cu, Ni/Au plating, 0.2-mm pitch (lead width 0.1 mm, spacing 0.1 mm)
Evaluation board II base material: 15-μm-thick polyimide, leads: 15-μm-thick Cu, Ni/Au plating, flying leads: 2 mm, 0.2-mm pitch (lead width 0.1 mm, spacing 0.1 mm)
High-temperature and high-humidity conditions: 85° C., 85% RH
Adhesion strength: 90° peeling

As is apparent from Table, with respect to the adhesion strength, in each of Comparative Examples B1 and B2, a high pressure of about 3 MPa is required to reduce the gap g. In this case, while the gap g is reduced to 2.0 to 2.5 μm, most of the ACF is forced out. As a result, the adhesion strength is reduced to a strength ratio of 0.2. However, the electrical resistance is maintained at a relatively low value. In each of Comparative Examples B3 and B4, while thermocompression bonding is performed under low-pressure conditions (pressure: 1 MPa), the gap g is as large as 3.5 μm or 4.8 μm because of the high elasticity of the Ni particles and the gold-plating resin balls. Thus, the ACF does not flow out, and the adhesion strength is relatively high. However, the electrical resistance is high from the beginning of the measurement and increases with time. After a predetermined time, the electrical continuity is broken.

In contrast, in each of Examples A1 to A3, in which the CMPWs are used as a conductive filler in the ACF, even when the thermocompression bonding is performed at a low pressure of 0.5 MPa to 1 MPa, it is possible to set the gap g in a small range of 0.5 μm to 1.0 μm. This is because the CMPWs have low elasticity, as has been repeatedly pointed out. In Examples A1 to A3, it is possible to ensure high-adhesion strength despite low-pressure mounting, and to maintain the electrical resistance at a constant low value from the beginning of measurement to about 500 hours.

While the embodiments of the present invention have been described above, the embodiments of the present invention disclosed above are merely illustrative. The scope of the present invention is not limited to the embodiments of the present invention. The scope of the present invention is shown by the scope of the claims, and is intended to include all modifications within the equivalent meaning and scope of the claims.

### INDUSTRIAL APPLICABILITY

According to a connection structure of printed circuit boards and so forth of the present invention, conductive leads of two printed circuit boards are subjected to thermocompression bonding at a low pressure such that the conductive leads are not deformed, so that a conductive connection with sufficiently high connection strength is easily established. In particular, in the case where the conductors of one printed circuit board are flying leads, the effect of low-pressure mounting is clearly provided. A conductive connection between fine-pitch conductors and the flying leads is reliably established, and high connection strength between both the printed circuit boards is provided.

### REFERENCE SIGNS LIST

10 (first) printed circuit board
11 base material
15 conductor (lead)
20 (second) printed circuit board
21 base material, 25 flying lead
31 release film
33 ACF
33a adhesive resin, 33p crystallized metal-particle wire
41 press tool
50 connection structure for circuit board
g gap between conductor and flying lead
D diameter of crystallized metal-particle wire
L length of crystallized metal-particle wire
S space between (conductor/flying lead) pairs, S₁ space between conductors, S₂ space between flying leads

### CITATION LIST

### Patent Literature

PTL 1: Japanese Unexamined Patent Application Publication No. 2007-173362

1. A connection structure of printed circuit boards, comprising:
a first printed circuit board;
a second printed circuit board located above the first printed circuit board; and
an anisotropic conductive adhesive configured to establish a conductive connection between a conductor of the first printed circuit board and a conductor of the second printed circuit board,
wherein the anisotropic conductive adhesive contains a conductive filler, and wherein the conductive filler is formed of crystallized metal-particle wires produced by allowing metal particles to crystallize and grow linearly.

2. The connection structure of printed circuit boards according to claim 1, wherein a gap defined as a distance between the conductor of the first printed circuit board and the conductor of the second printed circuit board is in the range of 0.1 μM to 3.0 μm.

3. The connection structure of printed circuit boards according to claim 1, wherein the second printed circuit board includes a flying lead serving as the conductor, and the anisotropic conductive adhesive establishes a conductive connection between the conductor of the first printed circuit board and the flying lead of the second printed circuit board.

4. The connection structure of printed circuit boards according to claim 1, wherein each of the crystallized metal-particle wires has a cross section in which many metal particles coalesce or pack, and wherein the metal particles form a protruding portion on the surface of each of the crystallized metal-particle wires.

5. The connection structure of printed circuit boards according to claim 1, wherein each of the crystallized metal-particle wires has a diameter of 0.3 μm or less.

6. The connection structure of printed circuit boards according to claim 1, wherein the volume fraction of the crystallized metal-particle wires contained in the anisotropic conductive adhesive is 0.1% by volume or less.

7. The connection structure of printed circuit boards according to claim 1, wherein the aspect ratio, i.e., length/diameter, of each of the crystallized metal-particle wires is 5 or more.

8. The connection structure of printed circuit boards according to claim 1, wherein the crystallized metal-particle wires are arranged along the direction of connection between the conductor of the first printed circuit board and the conductor of the second printed circuit board.

9. An anisotropic conductive adhesive configured to establish a conductive connection between a conductor of a first printed circuit board and a conductor of a second printed circuit board that is located above the first printed circuit board, the anisotropic conductive adhesive comprising:
a conductive filler, wherein the conductive filler is formed of crystallized metal-particle wires formed by allowing metal particles to crystallize and grow linearly.

10. The anisotropic conductive adhesive according to claim 9, wherein the anisotropic conductive adhesive is in the form of a film.

11. The anisotropic conductive adhesive according to claim 10, wherein the crystallized metal-particle wires are oriented in the thickness direction of the film.

12. A method for producing a connection structure of printed circuit boards, comprising the steps of:
preparing a first printed circuit board;
arranging an anisotropic conductive adhesive film on the first printed circuit board;
arranging a second printed circuit board on the anisotropic conductive adhesive film so as to correspond to the first printed circuit board; and
performing thermocompression bonding by applying a pressure from the second printed circuit board using a thermocompression bonding tool via a release film,
wherein in the step of arranging the anisotropic conductive adhesive film, a conductive filler contained in the anisotropic conductive adhesive film is formed of crystallized metal-particle wires formed by allowing metal particles to crystallize and grow linearly.

13. The method for producing a connection structure of printed circuit boards according to claim 12, wherein in the thermocompression bonding step, a gap defined as a distance between the conductor of the first printed circuit board and the conductor of the second printed circuit board is set in the range of 0.1 μm to 3.0 μm.

14. The method for producing a connection structure of printed circuit boards according to claim 12, wherein in the thermocompression bonding step, the pressure is set to 2 MPa or less.
